(19) United States
(12) Patent Application Publication
(10) Pub. No.: US 2026/0182435 A1
(43) Pub. Date: Jun. 25, 2026

(54) PACKAGE STRUCTURE AND METHOD OF MANUFACTURING PACKAGE STRUCTURE

(71) Applicant: Advanced Semiconductor Engineering, Inc., Kaohsiung (TW)

(72) Inventors: Wei-Jhen CIOU, Kaohsiung (TW); Fan Ting Hung, Kaohsiung (TW); Ya-Wen LIAO, Kaohsiung (TW); Jenchun CHEN, Kaohsiung (TW)

(73) Assignee: Advanced Semiconductor Engineering, Inc., Kaohsiung (TW)

(21) Appl. No.: 19/001,303

(22) Filed: Dec. 24, 2024

(51) Int. Cl. H01L 21/56; H01L 23/31; H01L 23/544

(52) U.S. Cl. CPC H10W 74/016; H10W 46/00; H10W 74/114; H10W 46/301

(57) ABSTRACT

Package structures and methods of manufacturing a package structure are disclosed. The method includes providing a carrier, wherein the carrier comprises an alignment mark; and attaching a mold chase to a first region of the carrier, wherein the alignment mark is outside the first region.

### BACKGROUND

### 1. Field of the Disclosure

The present disclosure relates to a package structure and a method of manufacturing a package structure.

### 2. Description of the Related Art

In a selective molding process of a package structure, there is a risk of a molding material overflowing into unintended areas, such as the region for electrical connections, which can result in a decrease in the yield rate of the package structure.

### SUMMARY

In some embodiments, a method of manufacturing a package structure includes providing a carrier, wherein the carrier includes an alignment mark; and attaching a mold chase to a first region of the carrier, wherein the alignment mark is outside the first region.

In some embodiments, a method of manufacturing a package structure includes providing a carrier including a first long side and a first supporter disposed adjacent to the first long side; and attaching a semiconductor die to the carrier, wherein the first supporter is free from overlapping the semiconductor die in a first direction substantially parallel to the first long side.

In some embodiments, a package structure during a manufacture of a package structure includes a carrier, a plurality of conductive pads, and an alignment mark. The carrier includes a long side. The conductive pads are disposed at a first surface of the carrier. The alignment mark is disposed at the first surface. The alignment mark overlaps the conductive pads in a first direction substantially perpendicular to the long side.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of an exemplary package structure according to some embodiments of the present disclosure.

FIG. 1A is a cross-sectional view of an exemplary package structure according to some embodiments of the present disclosure.

FIG. 2A illustrates one or more stages of an example of a method for manufacturing a package structure according to some embodiments of the present disclosure.

FIG. 2B is a top view of a box B2b in FIG. 2A.

FIG. 3 illustrates one or more stages of an example of a method for manufacturing a package structure according to some embodiments of the present disclosure.

FIG. 4A illustrates one or more stages of an example of a method for manufacturing a package structure according to some embodiments of the present disclosure.

FIG. 4B is a top view of a box B4b in FIG. 4A.

FIG. 5A illustrates one or more stages of an example of a method for manufacturing a package structure according to some embodiments of the present disclosure.

FIG. 5B is a top view of a box B5b in FIG. 5A.

FIG. 6A illustrates one or more stages of an example of a method for manufacturing a package structure according to some embodiments of the present disclosure.

FIG. 6B is a top view of a box B6b in FIG. 6A.

FIG. 7 is a cross-sectional view of an exemplary package structure according to some embodiments of the present disclosure.

FIG. 8A illustrates one or more stages of an example of a method for manufacturing a package structure according to some embodiments of the present disclosure.

FIG. 8B is a top view of a box B8b in FIG. 8A.

FIG. 8C is a cross-sectional view along the line 8C-8C′ in FIG. 8B.

FIG. 9A illustrates one or more stages of an example of a method for manufacturing a package structure according to some embodiments of the present disclosure.

FIG. 9B is a top view of a box B9b in FIG. 9A.

FIG. 10A illustrates one or more stages of an example of a method for manufacturing a package structure according to some embodiments of the present disclosure.

FIG. 10B is a top view of a box B10b in FIG. 10A.

FIG. 11A illustrates one or more stages of an example of a method for manufacturing a package structure according to some embodiments of the present disclosure.

FIG. 11B is a top view of a box B11b in FIG. 11A.

FIG. 12A illustrates one or more stages of an example of a method for manufacturing a package structure according to some embodiments of the present disclosure.

FIG. 12B is a top view of a box B12b in FIG. 12A.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for purposes of simplicity and clarity and does not in itself dictate a relationship between the various embodiments and/or configurations discussed.

The present disclosure provides a selective molding method for manufacturing a package structure. The method includes providing a carrier, wherein the carrier comprises an alignment mark disposed outside a landing region of a mold chase and/or additional conductive blocks (or patches) adjacent to the edges of the carrier configured to support the mold chase. In some cases, during the attachment of the mold chase, the weight thereof would deform a dielectric material of the carrier and a gap between the mold chase and the carrier would appear. A portion of the molding material may then overflow through the gap and arrive at a region for electrical connection (e.g., a wire bonding region). The yield would be adversely impacted. In the present disclosure, the additional conductive blocks (or patches) adjacent to the edges of the carrier are configured to support the weight of the mold chase. The deformation/dishing of the carrier can be significantly alleviated. The contacting surfaces of the mold chase and the carrier can be aligned closely or tightly pressed together, ensuring that no gaps will appear during the attachment of the mold chase. The risk of the mold material invading unwanted regions can be reduced. The yield rate of the package structure can be improved.

Furthermore, the alignment mark is disposed at a top surface of the carrier but is not smoothly continuous with the top surface. The uneven profile around the alignment mark may form an overflowing path beneath the mold chase. In the present disclosure, the alignment mark is designed to be outside the landing region of the mold chase. This guarantees the tightness between the mold chase and the top surface of the carrier. No gap would appear during the attachment of the mold chase. The risk of the mold material invading unwanted regions can be reduced. The yield of the package structure can be improved.

Additionally, the alignment mark and the additional conductive blocks (or patches) can be found in a structure during the manufacturing process of the package structure, while being removed, by, e.g., a singulation process. The alignment mark and the additional conductive blocks (or patches) may not be found in the package structure. Hence, the design of the routing/layout of the package structure would not be severely impacted, and the present disclosure can be implemented in or applied to the baseline manufacturing process.

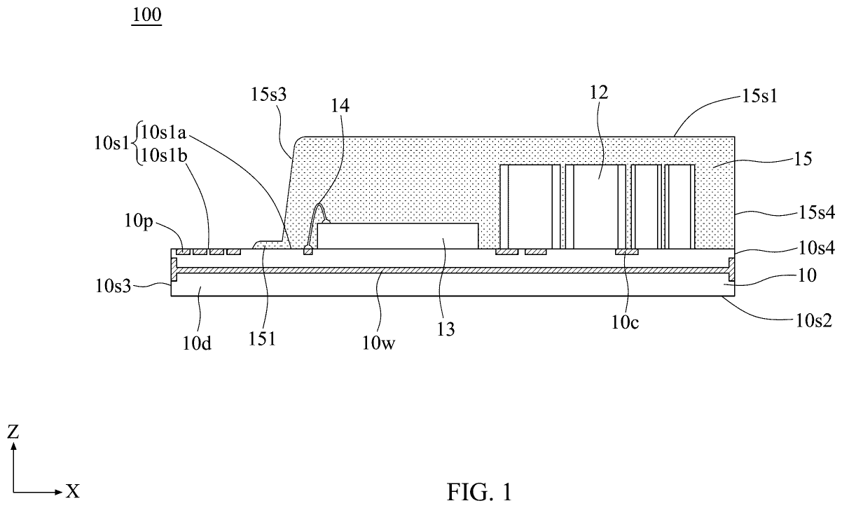

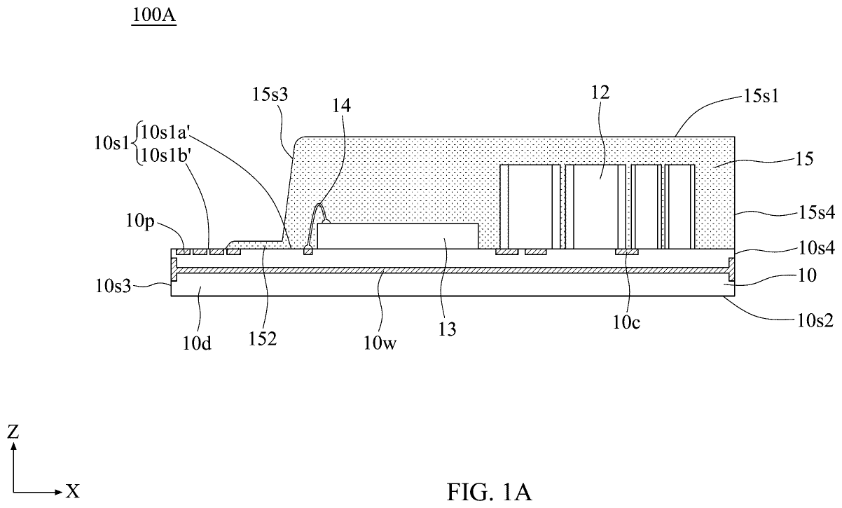

FIG. 1 is a cross-sectional view of an exemplary package structure 100 according to some embodiments of the present disclosure. The package structure 100 may include a carrier 10, one or more electrical components 12, a semiconductor die 13, a bond wire 14, and an encapsulation layer 15.

The carrier (or a substrate, a circuit structure) 10 may be, for example, a printed circuit board, such as a paper-based copper foil laminate, a composite copper foil laminate, or a polymer-impregnated glass-fiber-based copper foil laminate. The carrier 10 may include an interconnection structure 10r, such as a redistribution layer (RDL). In some embodiments, the carrier 10 may be a single-layer carrier or multi-layer carrier. The carrier 10 may include a dielectric layer 10d. The interconnection structure 10r may be embedded in the dielectric layer 10d.

The material of the dielectric layer 10d may include, for example, an organic material, such as a solder mask, a polyimide (PI), an Ajinomoto build-up film (ABF), and one or more molding compounds. The material of the dielectric layer 10d may include, for example, an inorganic material silicon-oxide (SiOₓ), or a silicon-nitride (SiNₓ). The interconnection structure 10r may include a conductive trace or a conductive via. The interconnection structure 10r is, or includes, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 10 has a surface 10s1 (also referred to as a first surface or a top surface) and a surface 10s2 (also referred to as a second surface or a bottom surface) opposite to the surface 10s1. The substrate 10 has a lateral surface 10s3 extending between the surface 10s1 and the surface 10s2. The substrate 10 has a lateral surface 10s4 opposite to and parallel with the lateral surface 10s3.

The carrier 10 may include a plurality of conductive pads (or pads) 10p disposed at the surface 10s1. The conductive pads 10p may be closer to the lateral surface 10s3 than to the lateral surface 10s4. The conductive pads 10p may be electrically connected to the interconnection structure 10r. The conductive pads 10p may be connected to bond wires (not shown). The conductive pads 10p may be configured to electrically connect the package structure to an external device/system. In some embodiments, the conductive pads 10p may be configured to optically couple to an external device/system. The conductive pads 10p may include a plurality of optical couplers (e.g., grating). The conductive pads 10p may be connected to a plurality of optical fibers.

The conductive pads 10p may be exposed by the encapsulation layer 15. The conductive pads 10p may not be covered by the encapsulation layer 15. If the conductive pads 10p are covered by a molding material, the electrical connection (or optical connection) would be hindered.

The conductive pads 10p are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 10 may include a plurality of conductive pads (or pads) 10c disposed at the surface 10s1. The conductive pads 10c may be electrically connected to the interconnection structure 10r. The conductive pads 10c may be connected to the electrical components 12 and/or the semiconductor die 13. A solder material (not shown) may connect the conductive pads 10c to the electrical components 12 and/or the semiconductor die 13. The conductive pads 10c may be partially covered by the encapsulation layer 15.

The conductive pads 10c are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The electrical components 12 may be disposed on the surface 10s1 of the carrier 10. The electrical components 12 may be covered or encapsulated by the encapsulation layer 15. The electrical components 12 may be an active component, such as an integrated circuit (IC) chip or a die. The electrical components 12 may be a passive electrical component, such as a capacitor, a resistor or an inductor. Each of the electrical components 12 may be electrically connected to one or more other electrical components 12 and to the carrier 10 (e.g., to the interconnection structure 10r), and electrical connection may be attained by way of flip-chip or wire-bond techniques.

The semiconductor die 13 may be disposed on the surface 10s1 of the carrier 10. The semiconductor die 13 may be covered or encapsulated by the encapsulation layer 15. The semiconductor die 13 and the electrical components 12 may be encapsulated by the same encapsulation layer (e.g., the encapsulation layer 15). In some embodiments, the semiconductor die 13 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the semiconductor die 13 may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). In some embodiments, the processing element may be a CPU chiplet, a MCU chiplet, a GPU chiplet, an ASIC chiplet, or the like. The memory element may be a cache memory. In some embodiments, the semiconductor die 13 may include a photonic processing unit. The semiconductor die 13 may be configured to process an optical signal. The semiconductor die 13 may be coupled to the carrier 10 through photonic bumps.

The bond wire 14 may connect the semiconductor die 13 (or a pad thereof) to one of the conductive pads 13c of the carrier 10. The bond wire 14 may have a curved profile.

The encapsulation layer 15 may be disposed on the surface 10s1 of the carrier 10. The encapsulation layer 15 covers a portion 10s1a of the surface 10s1 of the carrier 10 and exposes another portion 10s1b of the surface 10s1 of the carrier 10. The encapsulation layer 15 covers or encapsulates the electrical components 12 and/or the semiconductor die 13.

The encapsulation layer 15 includes a lateral surface 15s4 substantially coplanar with the lateral surface 10s4 of the carrier 10. The encapsulation layer 15 includes a lateral surface 15s3 opposite to the lateral surface 15s4. In some embodiments, the lateral surface 15s4 is inclined from a surface 15s1 of the encapsulation layer 15 to the surface 10s1 of the carrier 10. For example, the lateral surface 15s3 of the encapsulation layer 15 is not perpendicular to the surface 10s1 of the carrier 10. For example, the lateral surface 15s3 and the surface 10s1 of the carrier 10 define an angle less than 90 degrees.

In some embodiments, the encapsulation layer 15 includes an epoxy resin having fillers, a molding compound (e.g., an epoxy molding compound or another molding compound), a polyimide, a phenolic compound or material, a material with a silicone dispersed therein, or a combination thereof.

The encapsulation layer 15 may include a portion 151, referred to as an overflow portion. The portion 151 may protrude from the lateral surface 15s3 of the encapsulation layer. During the formation of the encapsulation layer 15, a mold chase is attached to the surface 10s1 of the carrier 10. The mold chase defines a region to be encapsulated and another region which is not to be encapsulated. The encapsulation layer 15 may be formed by selective molding. In some cases, a gap may appear between the foot of the mold chase and the carrier 10, and thus the mold material may overflow through the gap to form the portion 151. The portion 151 may not cover the conductive pads, allowing the electrical connection (or optical connection) to remain intact. Nevertheless, the existence of the overflow portion 151 would narrow the process window of the formation of the encapsulation layer 15. Once the relatively large variation of the amount of the mold material occurs, there is a risk that the size of the overflow portion 151 could increase and subsequently cover the electrical connection region.

FIG. 1A is a cross-sectional view of an exemplary package structure 100A according to some embodiments of the present disclosure. The package structure 100A in FIG. 1A is similar to the package structure 100 in FIG. 1. Therefore, some detailed descriptions may refer to corresponding preceding paragraphs and are not repeated hereinafter for conciseness, with differences therebetween as follows.

The encapsulation layer 15 covers a portion 10s1a′ of the surface 10s1 of the carrier 10 and exposes another portion 10s1b′ of the surface 10s1 of the carrier 10. In the X direction, the dimension of the portion 10s1b′ as shown in FIG. 1A may be smaller than that of the portion 10s1b as shown in FIG. 1.

The encapsulation layer 15 may cover one or more of the conductive pads 10p. The encapsulation layer 15 may include a portion 152, referred to as an overflow portion. During the formation of the encapsulation layer 15, a mold chase is attached to the surface 10s1 of the carrier 10. The mold chase defines a region to be encapsulated and another region which is not to be encapsulated. In some cases, a gap may appear between the foot of the mold chase and the carrier 10, and thus the mold material may overflow through the gap to form the portion 152. The portion 152 would cover one or more of the conductive pads, and then the electrical connection (or optical connection) would be adversely impacted. The yield rate of the package structure 100A would be lessened.

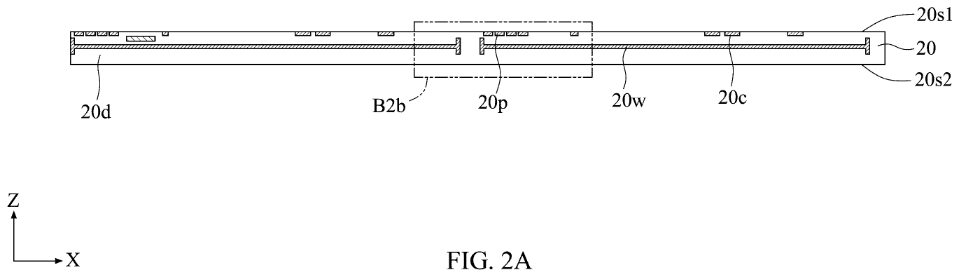

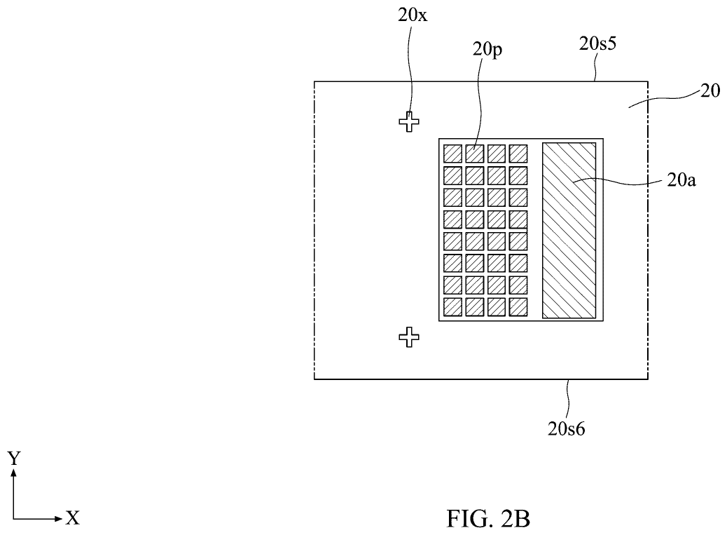

FIG. 2A illustrates one or more stages of an example of a method for manufacturing a package structure (e.g., the package structure 100 or 100A) according to some embodiments of the present disclosure.

As shown in FIG. 2A, a carrier 20 may be provided. The carrier 20 may include a panel or strip. The carrier 20 may have a substantially rectangular shape.

The carrier (or a substrate, a circuit structure) 20 may be, for example, a printed circuit board, such as a paper-based copper foil laminate, a composite copper foil laminate, or a polymer-impregnated glass-fiber-based copper foil laminate. The carrier 20 may include an interconnection structure 20r, such as a redistribution layer (RDL). In some embodiments, the carrier 20 may be a single-layer carrier or multi-layer carrier. The carrier 20 may include a dielectric layer 20d. The interconnection structure 20r may be embedded in the dielectric layer 20d.

The material of the dielectric layer 20d may include, for example, an organic material, such as a solder mask, a polyimide (PI), an Ajinomoto build-up film (ABF), and one or more molding compounds. The material of the dielectric layer 20d may include, for example, an inorganic material silicon-oxide (SiOₓ), or a silicon-nitride (SiNₓ). The interconnection structure 20r may include a conductive trace or a conductive via. The interconnection structure 20r is, or includes, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 20 has a surface 20s1 (also referred to as a first surface or a top surface) and a surface 20s2 (also referred to as a second surface or a bottom surface) opposite to the surface 20s1.

The carrier 20 may include a plurality of conductive pads (or pads) 20p disposed at the surface 20s1. The conductive pads 20p may be electrically connected to the interconnection structure 20r. The conductive pads 20p may be connected to bond wires (not shown). The conductive pads 20p may be configured to electrically connect the package structure to an external device/system. In some embodiments, the conductive pads 20p may be configured to optically couple to an external device/system. The conductive pads 20p may include a plurality of optical couplers (e.g., grating). The conductive pads 20p may be connected to a plurality of optical fibers. The conductive pads 20p are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 20 may include a plurality of conductive pads (or pads) 20c disposed at the surface 20s1. The conductive pads 20c may be electrically connected to the interconnection structure 20r. The conductive pads 20c are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

FIG. 2B is a top view of a box B2b in FIG. 2A. The conductive pads 20p may include an array of conductive pads. The carrier 20 may include one or more alignment marks 20x disposed adjacent to long sides (or edges) 20s5 and 20s6. The alignment marks 20x may have a surface discontinuous with the surface 20s1 of the carrier 20. The alignment marks 20x may be used for the alignment during the manufacture of the package structure 100. The alignment marks 20x may have a cross shape. In some embodiments, the alignment marks 20x may have a grating. The one or more alignment marks 20x may not overlap the conductive pads 20p in a direction substantially parallel to the long side 20s5 of the carrier 20 (i.e., the X direction). The one or more alignment marks 20x may not overlap the conductive pads 20p in a direction substantially perpendicular to the long side 20s5 of the carrier 20 (i.e., the Y direction).

The carrier 20 may further include a conductive block 20a disposed adjacent to the conductive pads 20p. The conductive block 20a may overlap the conductive pads 20p in a direction substantially parallel to the long side 20s5 of the carrier 20 (i.e., the X direction). The conductive block 20a may be buried in the carrier 20.

The alignment marks 20x and the conductive block 20a are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

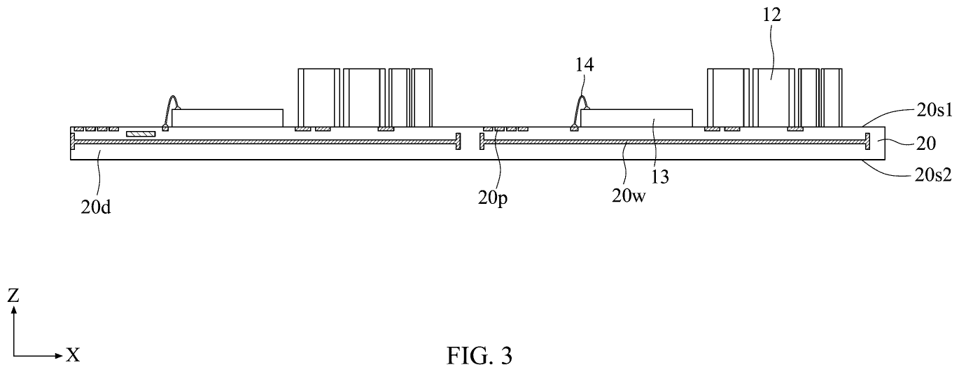

FIG. 3 illustrates one or more stages of an example of a method for manufacturing a package structure (e.g., the package structure 100 or 100A) according to some embodiments of the present disclosure.

As shown in FIG. 3, one or more electrical components 12 may be attached to or mounted on the surface 20s1 of the carrier 20. A semiconductor die 13 may be attached to or mounted on the surface 20s1 of the carrier 20. The electrical components 12 may be located adjacent to the semiconductor die 13. The electrical components 12 may be mounted to the conductive pads 20c through solder bumps (not shown). The semiconductor die 13 may be mounted to the conductive pads 20c through solder bumps (not shown).

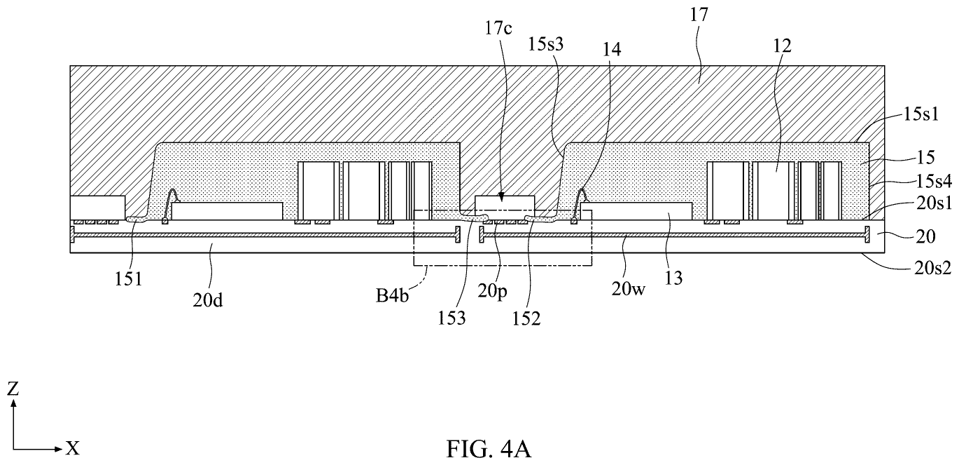

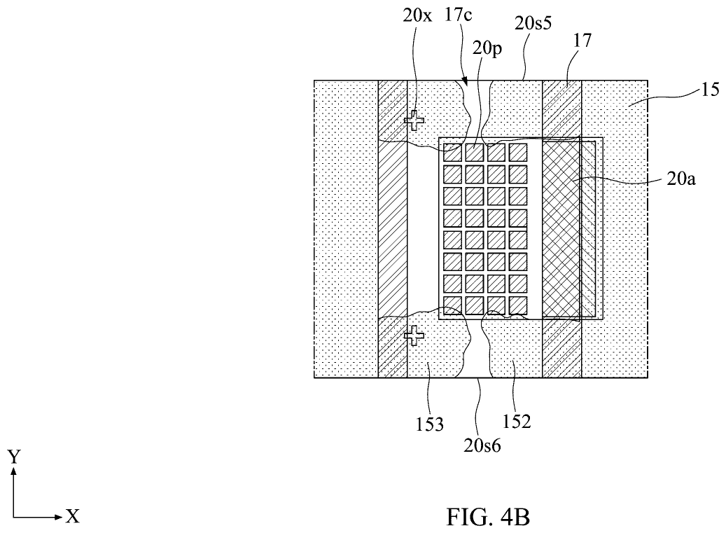

FIG. 4A illustrates one or more stages of an example of a method for manufacturing a package structure (e.g., the package structure 100 or 100A) according to some embodiments of the present disclosure.

As shown in FIG. 4A, a mold chase 17 may be attached to the carrier 20 (i.e., the surface 20s1). A molding material may be transferred into a space defined by the mold chase 17 to form an encapsulation layer 15. The mold chase 17 may define the profile of the encapsulation layer 15. The stages of the method for manufacturing the package structure may include covering or encapsulating the electrical components 12 and the semiconductor die 13 by the encapsulation layer 15.

The mold chase 17 may define a cavity 17c for exposing the conductive pads 20p. The mold material would not be transferred into the cavity 17c. The mold chase 17 is designed to selectively transfer or apply the mold material to different portions of the surface 20s1 of the carrier 20. As such, the electrical components and the semiconductor die 13 can be encapsulated by the encapsulation layer 15, while the conductive pads 20p may be exposed.

During the attachment of the mold chase, the weight thereof would deform the dielectric layer 20d of the carrier 20 and a gap between the mold chase 17 and the carrier 20 would appear. A portion of the molding material may overflow through the gap and arrive at the cavity 17c. A portion 151, a portion 152, and/or a portion 153 may be formed during the formation of the encapsulation layer 15.

FIG. 4B is a top view of a box B4b in FIG. 4A. The portion 152 may protrude from the encapsulation layer 15. The portion 152 may overflow the mold chase 17 and cover a portion of the conductive pads 12p. The mold chase 17 may overlap the conductive block 20a. The conductive block 20a may be relatively rigid, such that the deformation/dishing of a middle portion of the carrier 20 can be lessened. In some embodiments, an edge portion of the carrier 20 (e.g., closer to the long sides (edges) 20s5 and 20s6 of the carrier 20) may be softer than its middle portion. As a result, the deformation/dishing of the edge portion of the carrier 20 would be more severe. Gaps between the mold chase 17 and the edge portion of the carrier 20 would appear and the mold material would overflow through the gaps. Hence, the portion 152 is generally located at the edge portion of the carrier 20.

The mold chase 17 may overlap the alignment marks 20x. The alignment marks 20x are not smoothly continuous with the surface 20s1 of the carrier 20. The uneven profile around the alignment mark 20x may form an overflowing path beneath the mold chase 17. The portion 153 may overflow the mold chase 17 and cover a portion of the conductive pads 12p. The portion 153 may protrude from the encapsulation layer 15. The conductive pads 20p may be partially covered by the portion 152 and the portion 153 of the encapsulation layer 15.

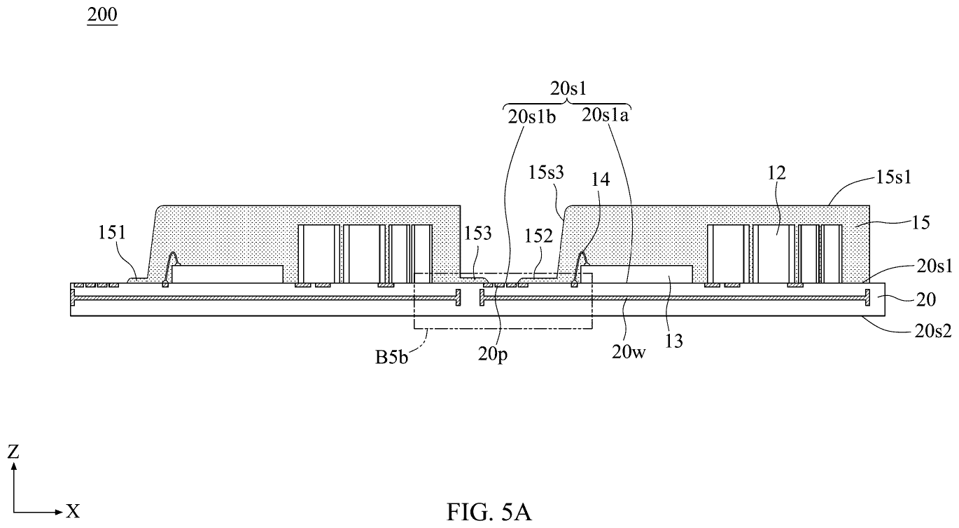

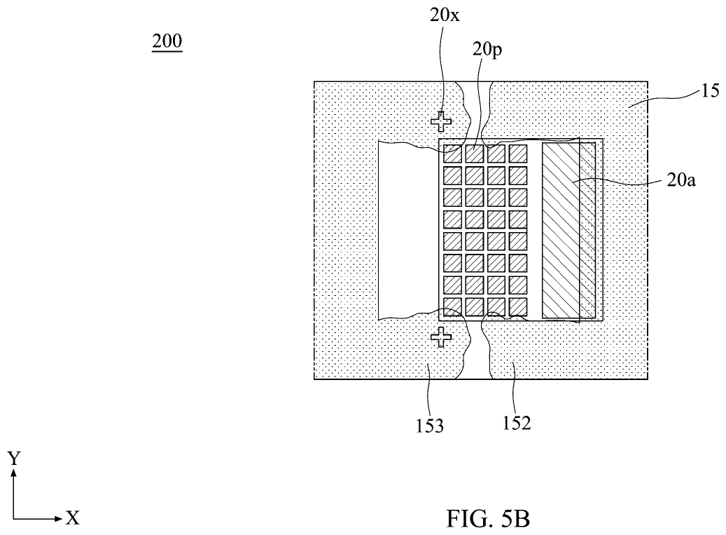

FIG. 5A illustrates one or more stages of an example of a method for manufacturing a package structure (e.g., the package structure 100 or 100A) according to some embodiments of the present disclosure. FIG. 5B is a top view of a box B5b in FIG. 5A.

As shown in FIG. 5A, the mold chase 17 may be removed to form a package structure 200. In some embodiments, the package structure 200 may be an intermediate structure during the manufacture of the package structure 100 (or 100A). The package structure 200 may be an intermediate structure after the formation of the encapsulation layer 15 and prior to the singulation process. A portion 20s1a of the surface 20s1 may be covered by the encapsulation layer 15, and a portion 20s1b of the surface 20s1 may be exposed by the encapsulation layer 15. As shown in FIG. 5B, owing to the overflow portions 151, 152, and 153, the portion 20s1b may be smaller than the distribution area of the conductive pads 20p. The electrical connection (or optical connection) between the conductive pads 20p and bond wires (not shown) would be adversely impacted. The yield rate of the package structure 100 or 100A would be lessened.

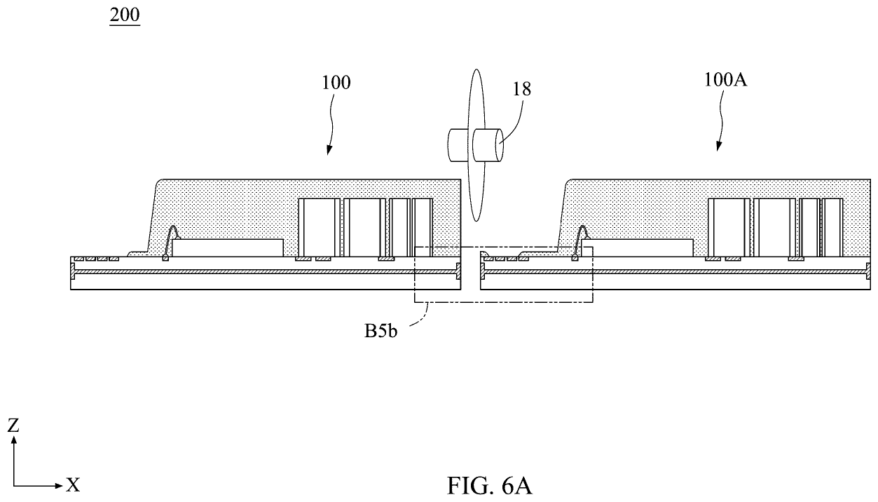

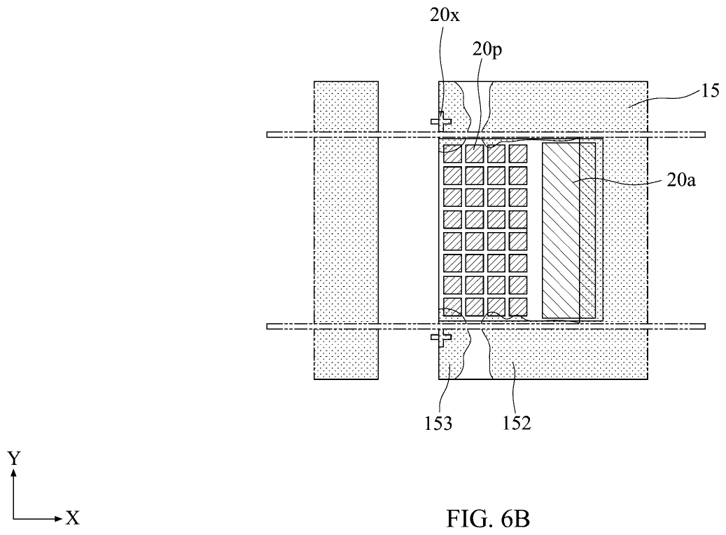

FIG. 6A illustrates one or more stages of an example of a method for manufacturing a package structure (e.g., the package structure 100 or 100A) according to some embodiments of the present disclosure.

As shown in FIG. 6A, the package structure 200 (or the carrier 20) may be singulated by a blade 18 to form a package structure 100 as shown in FIG. 1 and/or a package structure 100A as shown in FIG. 1A.

FIG. 6B is a top view of a box B6b in FIG. 6A. The edge portion of the carrier 20 may be removed by a singulation process. The alignment mark 20x may be removed and would not be found in the package structure 100 or 100A.

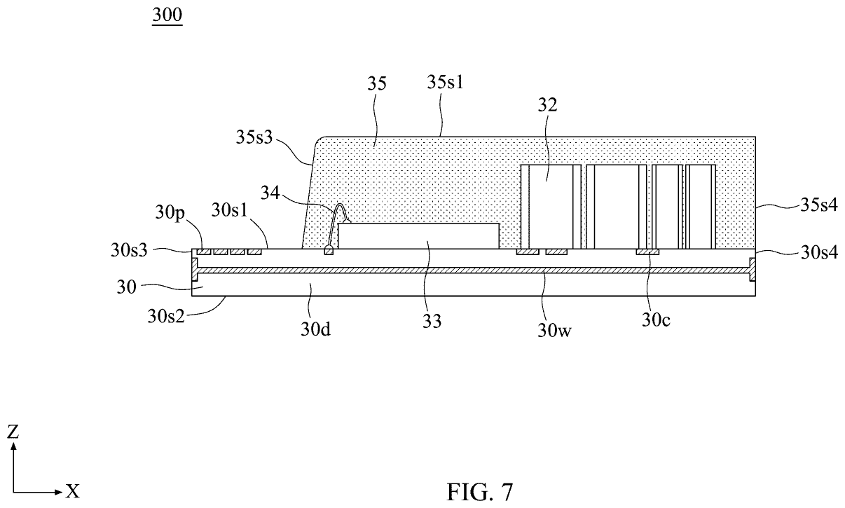

FIG. 7 is a cross-sectional view of an exemplary package structure according to some embodiments of the present disclosure. The package structure 300 may include a carrier 30, one or more electrical components 32, a semiconductor die 33, a bond wire 34, and an encapsulation layer 35.

The carrier (or a substrate, a circuit structure) 30 may be, for example, a printed circuit board, such as a paper-based copper foil laminate, a composite copper foil laminate, or a polymer-impregnated glass-fiber-based copper foil laminate. The carrier 30 may include an interconnection structure 30r, such as a redistribution layer (RDL). In some embodiments, the carrier 30 may be a single-layer carrier or multi-layer carrier. The carrier 30 may include a dielectric layer 30d. The interconnection structure 30r may be embedded in the dielectric layer 30d.

The material of the dielectric layer 30d may include, for example, an organic material, such as a solder mask, a polyimide (PI), an Ajinomoto build-up film (ABF), and one or more molding compounds. The material of the dielectric layer 30d may include, for example, an inorganic material silicon-oxide (SiOₓ), or a silicon-nitride (SiNₓ). The interconnection structure 30r may include a conductive trace or a conductive via. The interconnection structure 30r is, or includes, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 30 has a surface 30s3 (also referred to as a first surface or a top surface) and a surface 30s2 (also referred to as a second surface or a bottom surface) opposite to the surface 30s3. The substrate 30 has a lateral surface 30s3 extending between the surface 30s3 and the surface 30s2. The substrate 30 has a lateral surface 30s4 opposite to and parallel with the lateral surface 30s3.

The carrier 30 may include a plurality of conductive pads (or pads) 30p disposed at the surface 30s3. The conductive pads 30p may be closer to the lateral surface 30s3 than to the lateral surface 30s4. The conductive pads 30p may be electrically connected to the interconnection structure 30r. The conductive pads 30p may be connected to bond wires (not shown). The conductive pads 30p may be configured to electrically connect the package structure to an external device/system. In some embodiments, the conductive pads 30p may be configured to optically couple to an external device/system. The conductive pads 30p may include a plurality of optical couplers (e.g., grating). The conductive pads 30p may be connected to a plurality of optical fibers.

The conductive pads 30p may be exposed by the encapsulation layer 35. The conductive pads 30p may not be covered by the encapsulation layer 35. If the conductive pads 30p are covered by a molding material, the electrical connection (or optical connection) would be hindered.

The conductive pads 30p are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 30 may include a plurality of conductive pads (or pads) 30c disposed at the surface 30s3. The conductive pads 30c may be electrically connected to the interconnection structure 30r. The conductive pads 30c may be connected to the electrical components 32 and/or the semiconductor die 33. A solder material (not shown) may connect the conductive pads 30c to the electrical components 32 and/or the semiconductor die 33. The conductive pads 30c may be partially covered by the encapsulation layer 35.

The conductive pads 30c are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The electrical components 32 may be disposed on the surface 30s3 of the carrier 30. The electrical components 32 may be covered or encapsulated by the encapsulation layer 35. The electrical components 32 may be an active component, such as an integrated circuit (IC) chip or a die. The electrical components 32 may be a passive electrical component, such as a capacitor, a resistor or an inductor. Each of the electrical components 32 may be electrically connected to one or more other electrical components 32 and to the carrier 30 (e.g., to the interconnection structure 30r), and electrical connection may be attained by way of flip-chip or wire-bond techniques.

The semiconductor die 33 may be disposed on the surface 30s3 of the carrier 30. The semiconductor die 33 may be covered or encapsulated by the encapsulation layer 35. The semiconductor die 33 and the electrical components 32 may be encapsulated by the same encapsulation layer (e.g., the encapsulation layer 35). In some embodiments, the semiconductor die 33 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the semiconductor die 33 may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). In some embodiments, the processing element may be a CPU chiplet, a MCU chiplet, a GPU chiplet, an ASIC chiplet, or the like. The memory element may be a cache memory. In some embodiments, the semiconductor die 33 may include a photonic processing unit. The semiconductor die 33 may be configured to process an optical signal. The semiconductor die 33 may be coupled to the carrier 30 through photonic bumps.

The bond wire 34 may connect the semiconductor die 33 (or a pad thereof) to one of the conductive pads 33c of the carrier 30. The bond wire 34 may have a curved profile.

The encapsulation layer 35 may be formed by selective molding. The encapsulation layer 35 may be disposed on the surface 30s3 of the carrier 30. The encapsulation layer 35 covers a portion 30s3a of the surface 30s3 of the carrier 30 and exposes another portion 30s3b of the surface 30s3 of the carrier 30. The encapsulation layer 35 covers or encapsulates the electrical components 32 and/or the semiconductor die 33. The encapsulation layer 35 may free from cover the conductive pads 30p.

The encapsulation layer 35 includes a lateral surface 35s4 substantially coplanar with the lateral surface 30s4 of the carrier 30. The encapsulation layer 35 includes a lateral surface 35s3 opposite to the lateral surface 35s4. In some embodiments, the lateral surface 35s4 is inclined from a surface 35s3 of the encapsulation layer 35 to the surface 30s3 of the carrier 30. For example, the lateral surface 35s3 of the encapsulation layer 35 is not perpendicular to the surface 30s3 of the carrier 30. For example, the lateral surface 35s3 and the surface 30s3 of the carrier 30 define an angle less than 90 degrees.

In some embodiments, the encapsulation layer 35 includes an epoxy resin having fillers, a molding compound (e.g., an epoxy molding compound or another molding compound), a polyimide, a phenolic compound or material, a material with a silicone dispersed therein, or a combination thereof.

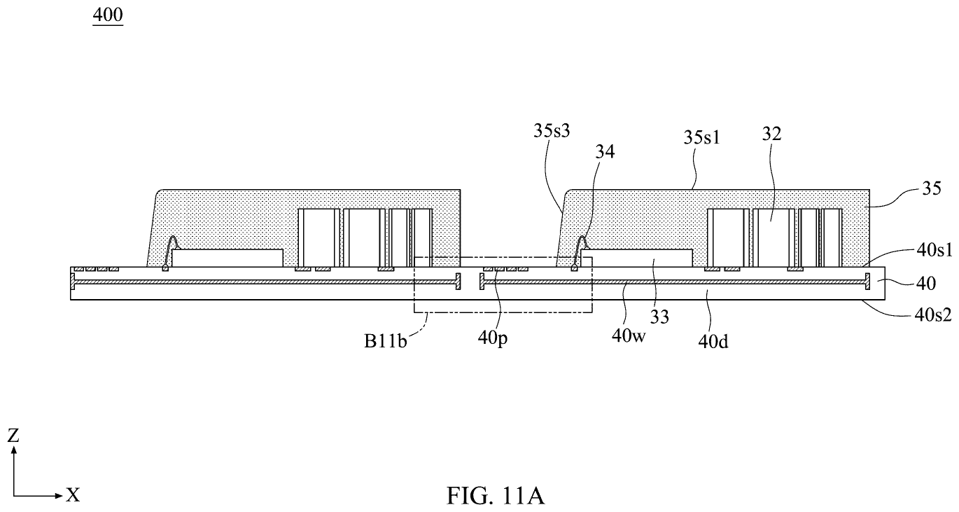

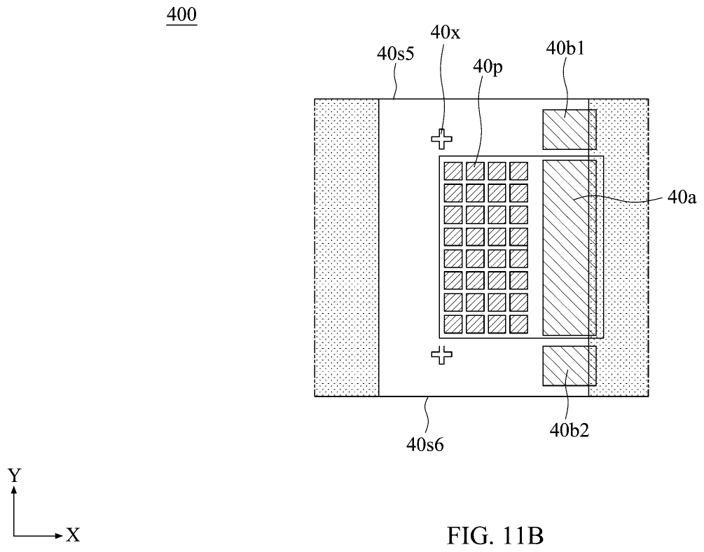

A package structure (e.g., the package structure 400 as shown in FIGS. 11A and 11B) during the manufacture of the package structure 300 may include a redesigned alignment mark and additional supporters. The redesigned alignment mark is outside the landing region of a mold chase. The additional supporters reinforce the rigidity of the carrier. During the formation of the encapsulation layer 35, the mold material can be restrained in the space defined by a mold chase without overflow. The encapsulation layer 35 may not include any portion protruding from the lateral surface 35s3 and may not cover the conductive pads 30p. The detailed descriptions of the package structure 400 and the manufacture of the package structure 300 will be discussed later.

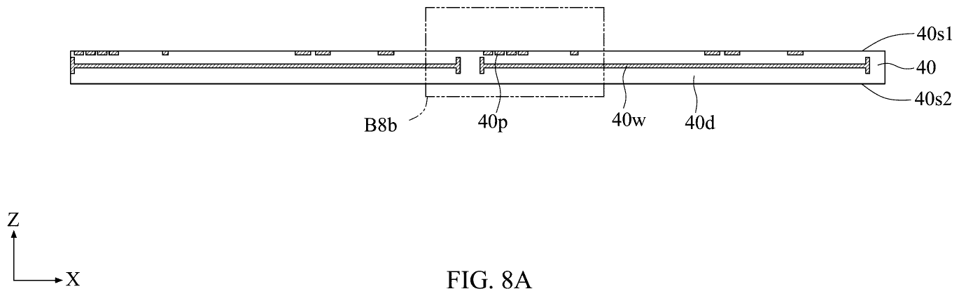

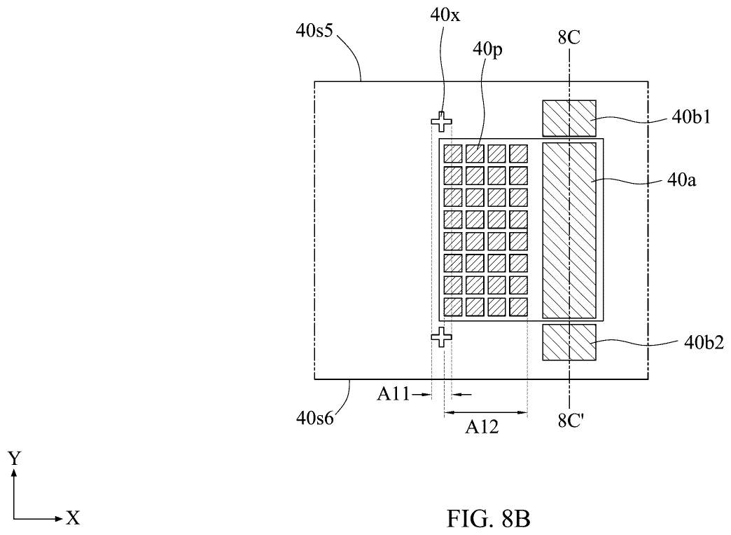

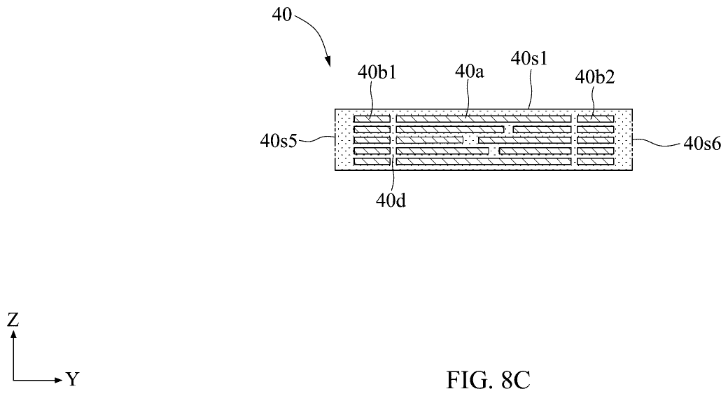

FIG. 8A illustrates one or more stages of an example of a method for manufacturing a package structure according to some embodiments of the present disclosure.

As shown in FIG. 8A, a carrier 40 may be provided. The carrier 40 may include a panel or strip. The carrier 40 may have a substantially rectangular shape.

The carrier (or a substrate, a circuit structure) 40 may be, for example, a printed circuit board, such as a paper-based copper foil laminate, a composite copper foil laminate, or a polymer-impregnated glass-fiber-based copper foil laminate. The carrier 40 may include an interconnection structure 40r, such as a redistribution layer (RDL). In some embodiments, the carrier 40 may be a single-layer carrier or multi-layer carrier. The carrier 40 may include a dielectric layer 40d. The interconnection structure 40r may be embedded in the dielectric layer 40d.

The material of the dielectric layer 40d may include, for example, an organic material, such as a solder mask, a polyimide (PI), an Ajinomoto build-up film (ABF), and one or more molding compounds. The material of the dielectric layer 40d may include, for example, an inorganic material silicon-oxide (SiOₓ), or a silicon-nitride (SiNₓ). The interconnection structure 40r may include a conductive trace or a conductive via. The interconnection structure 40r is, or includes, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 40 has a surface 40s1 (also referred to as a first surface or a top surface) and a surface 40s2 (also referred to as a second surface or a bottom surface) opposite to the surface 40s1.

The carrier 40 may include a plurality of conductive pads (or pads) 40p disposed at the surface 40s1. The conductive pads 40p may be electrically connected to the interconnection structure 40r. The conductive pads 40p may be connected to bond wires (not shown). The conductive pads 40p may be configured to electrically connect the package structure to an external device/system. In some embodiments, the conductive pads 40p may be configured to optically couple to an external device/system. The conductive pads 40p may include a plurality of optical couplers (e.g., grating). The conductive pads 40p may be connected to a plurality of optical fibers. The conductive pads 40p are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

The carrier 40 may include a plurality of conductive pads (or pads) 40c disposed at the surface 40s1. The conductive pads 40c may be electrically connected to the interconnection structure 40r. The conductive pads 40c are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof.

FIG. 8B is a top view of a box B8b in FIG. 8A. The conductive pads 40p may include an array of conductive pads. The carrier 40 may include one or more alignment marks 40x disposed at the surface 40s1. The alignment marks 40x may be disposed adjacent to long sides (or edges) 40s5 and 40s6. A surface of the alignment marks 40x may be discontinuous with the surface 40s1. The alignment marks 40x may be recessed from the surface 40s1. The alignment marks 40x may be used for the alignment during the manufacture of the package structure 100. The alignment marks 40x may have a cross shape. In some embodiments, the alignment marks 40x may have a grating. The one or more alignment marks 40x may not overlap the conductive pads 40p in a direction substantially parallel to the long side 40s5 of the carrier 40 (i.e., the X direction). The one or more alignment marks 40x may (partially) overlap the conductive pads 40p in a direction substantially perpendicular to the long side 40s5 of the carrier 40 (i.e., the Y direction). The alignment marks 40x may have a projection area A11 on the long side 40s6 of the carrier 40. The conductive pads 40p may have a projection area A12 on the long side 40s6 of the carrier 40. The projection area A11 may partially overlap the projection area A12.

The carrier 40 may further include a conductive block 40a disposed adjacent to the conductive pads 40p. The conductive block 40a may overlap the conductive pads 40p in a direction substantially parallel to the long side 40s5 of the carrier 40 (i.e., the X direction). The conductive block 40a may be buried in the carrier 40.

The carrier 40 may further include a supporter 40b1 and a supporter 40b2. The supporter 40b1 may be disposed adjacent to the long side (or edge) 40s5. The supporter 40b1 may overlap the supporter 40b2 in a direction substantially perpendicular to the long side 40s5 (e.g., the Y direction). The supporter 40b1 and/or the supporter 40b2 may be dummy patches, which means they are not configured to transmit electrical signals. The supporter 40b2 may be disposed adjacent to the long side (or edge) 40s6. The supporter 40b1 and the supporter 40b2 may be embedded in the carrier 40 (or the dielectric layer 40d). The supporter 40b1 and the supporter 40b2 may be covered by a solder mask of the carrier 40 at the surface 40s1. The supporter 40b1 and the supporter 40b2 may be free from overlapping the conductive pads 40p in a direction substantially parallel to the long side 40s5 of the carrier 40 (i.e., the X direction).

FIG. 8C is a cross-sectional view along the line 8C-8C′ in FIG. 8B. As shown in FIG. 8, the supporter 40b1 and the supporter 40b2 may surround the conductive block 40a. The supporter 40b1 or 40b2 may include a stacking structure. The supporter 40b1 and/or the supporter 40b2 may be configured to reinforce the rigidity of the edge portion of the carrier 40 (e.g., around the long sides 40s5 and 40s6).

Referring back to FIG. 8B, the one or more alignment marks 40x may overlap the supporter 40b1 and/or the supporter 40b2 in a direction substantially parallel to the long side 40s5 of the carrier 40 (i.e., the X direction).

The alignment marks 40x, the conductive block 40a, the supporter 40b1, and the supporter 40b2 are, or include, a conductive material such as a metal or metal alloy. Examples of the conductive material include gold (Au), silver (Ag), copper (Cu), platinum (Pt), Palladium (Pd), other metal(s) or alloy(s), or a combination of two or more thereof. In some embodiments, the supporter 40b1 and/or the supporter 40b2 may include conductive patches.

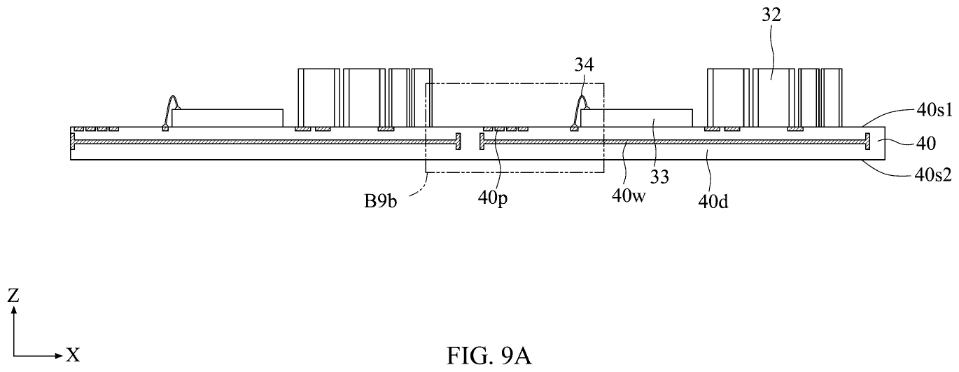

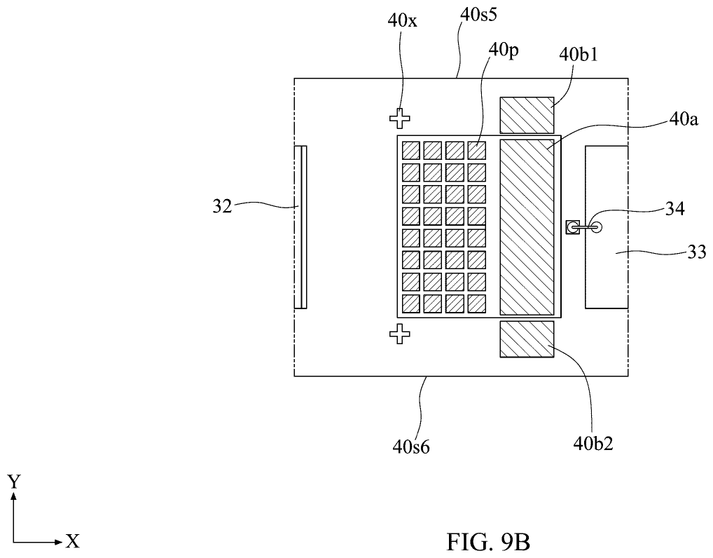

FIG. 9A illustrates one or more stages of an example of a method for manufacturing a package structure (e.g., the package structure 300) according to some embodiments of the present disclosure.

As shown in FIG. 9A, one or more electrical components 32 may be attached to or mounted on the surface 40s1 of the carrier 40. A semiconductor die 33 may be attached to or mounted on the surface 40s1 of the carrier 40. The electrical components 32 may be located adjacent to the semiconductor die 33. The electrical components 32 may be mounted to the conductive pads 40c through solder bumps (not shown). The semiconductor die 33 may be mounted to the conductive pads 40c through solder bumps (not shown).

In some embodiments, the stages of the method for manufacturing a package structure in FIG. 9A may further include forming a bond wire 34 to connect the carrier 40 to the semiconductor die 33. The bond wire 34 may have a curved shape.

FIG. 9B is a top view of a box B9b in FIG. 9A. The one or more alignment marks 40x may be free from overlapping the electrical components 32 in a direction substantially parallel to the long side 40s5 of the carrier 40 (i.e., the X direction). The one or more alignment marks 40x may be free from overlapping the semiconductor die 33 in a direction substantially parallel to the long side 40s5 of the carrier 40 (i.e., the X direction).

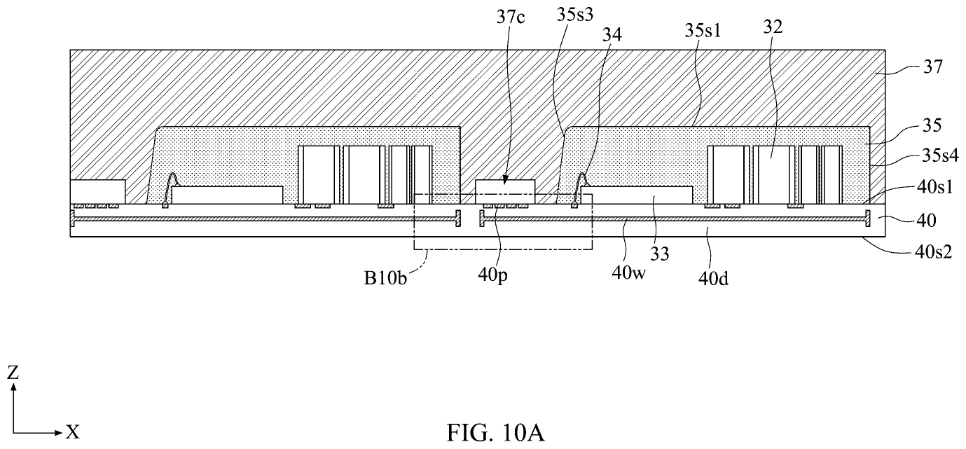

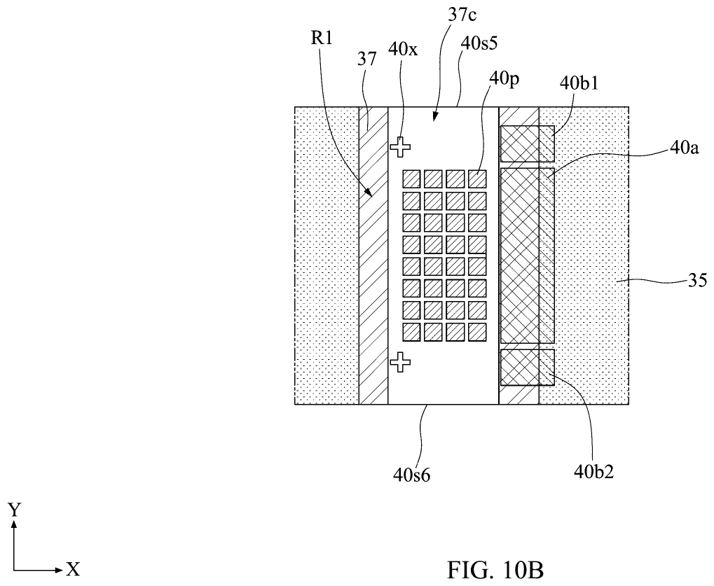

FIG. 10A illustrates one or more stages of an example of a method for manufacturing a package structure (e.g., the package structure 300) according to some embodiments of the present disclosure.

As shown in FIG. 10A, a mold chase 37 may be attached to the carrier 40 (i.e., the surface 40s1). A molding material may be transferred into a space defined by the mold chase 37 to form an encapsulation layer 35. The mold chase 37 may define the profile of the encapsulation layer 35. The stages of the method for manufacturing the package structure may include covering or encapsulating the electrical components 32 and the semiconductor die 33 by the encapsulation layer 35.

The mold chase 37 may define a cavity 37c for exposing the conductive pads 40p. The mold material would not be transferred into the cavity 37c. The mold chase 37 is designed to selectively transfer or apply the mold material to different portions of the surface 40s1 of the carrier 40. The encapsulation layer 35 may be separated from the cavity 37c. As such, the electrical components and the semiconductor die 33 can be encapsulated by the encapsulation layer 35, while the conductive pads 40p may be exposed.

In some cases, the weight of a mold chase 37 would deform a carrier, and a gap between the mold chase and the carrier would appear. A portion of the molding material may then overflow through the gap and then cover a wire bond area. In the present disclosure, additional supporters (e.g., the supporter 40b1 and the supporter 40b2) can prevent the overflow. The supporter 40b1 and the supporter 40b2 can support a solder mask of the carrier 40 (at the surface 40s1 of FIG. 8C). The solder mask above the conductive block 40a, the supporter 40b1, and the supporter 40b2 may have substantially flat surface. In other words, a portion of the solder mask directly above the conductive block 40a and the other portion of the solder mask directly above the supporters 40b1 and 40b2 may be at substantially the same elevation. No step height or a step height with acceptable amount exists between theses portions. The bottom surface of the mold chase 35 in FIG. 10A can fit the solder mask of the carrier 40 to prevent any gaps therebetween. Thus, the overflow of the encapsulation layer 35 can be prevented.

FIG. 10B is a top view of a box B10b in FIG. 10A. The mold chase 37 may overlap the conductive block 40a. The conductive block 40a may be relatively rigid, such that the deformation/dishing of a middle portion of the carrier 40 can be lessened.

The mold chase 37 may be above the supporter 40b1 and/or the supporter 40b2. The mold chase 37 may overlap the supporter 40b1 and/or the supporter 40b2 in the direction substantially perpendicular to the surface 40s1. The additional supporters 40b1 and 40b2 reinforce the rigidity of the edge portion of the carrier 40. The additional supporters 40b1 and 40b2 are configured to support the mold chase 37 for alleviating a deformation (or dishing) of the carrier 40. During the formation of the encapsulation layer 35, the mold material can be restrained in the space defined by the mold chase 37 without overflow. The contacting surfaces of the mold chase 37 and the carrier 40 can be aligned closely or tightly pressed together, ensuring that no gaps will appear during the attachment of the mold chase 37. The encapsulation layer 35 may be separated from the supporter 40b1 and the supporter 40b2. The risk of the mold material invading unwanted regions can be reduced. The yield rate of the package structure 300 can be improved.

Furthermore, a redesigned alignment mark (e.g., the alignment mark(s) 40x) being outside the landing region of the mold chase can prevent the overflow. The mold chase 37 may be attached to a region (or a landing region) R1 of the carrier 40. The mold chase 37 may not overlap the alignment marks 40x. The mold chase 37 may be separated from the alignment mark 40x. The alignment marks 40x may be outside the region R1. The region R1 may not overlap the alignment marks 40x in the direction substantially perpendicular to the surface 40s1. In some embodiments, the cavity 37c of the mold chase may be directly above the alignment mark 40x. The alignment mark 40x may be separated from the encapsulation layer 35.

The uneven profile around the alignment mark 40x would not interfere the contact between the mold chase 37 and the carrier 40. This guarantees the tightness between the mold chase 37 and the surface 40s1 of the carrier 40. No gap would appear during the attachment of the mold chase 37. During the formation of the encapsulation layer 35, the mold material can be restrained in the space defined by the mold chase 37 without overflow. The risk of the mold material invading unwanted regions can be reduced. The yield of the package structure can be improved.

FIG. 11A illustrates one or more stages of an example of a method for manufacturing a package structure (e.g., the package structure 300) according to some embodiments of the present disclosure. FIG. 11B is a top view of a box B11b in FIG. 11A.

As shown in FIG. 11A, the mold chase 37 may be removed to form a package structure 400. In some embodiments, the package structure 400 may be an intermediate structure during the manufacturing process of the package structure 300. The package structure 400 may be an intermediate structure after the formation of the encapsulation layer 35 and prior to the singulation process. A portion 40s1a of the surface 40s1 may be covered by the encapsulation layer 35, and a portion 40s1b of the surface 40s1 may be exposed by the encapsulation layer 35. As shown in FIG. 11B, no overflow portion appears over the conductive pads 40p.

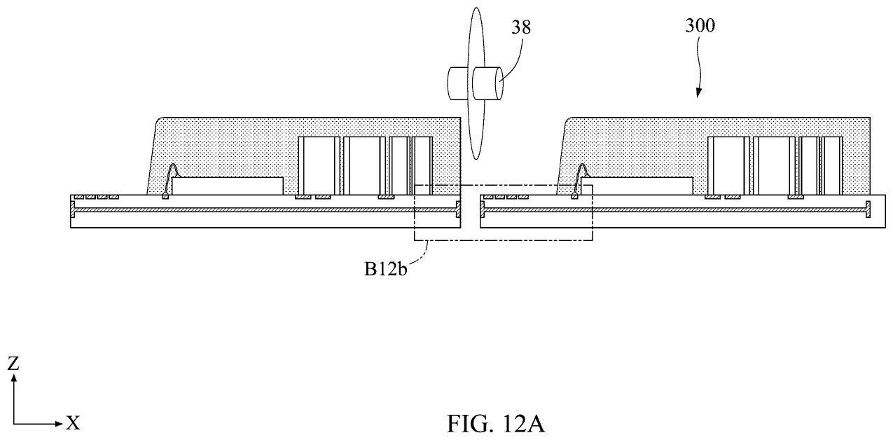

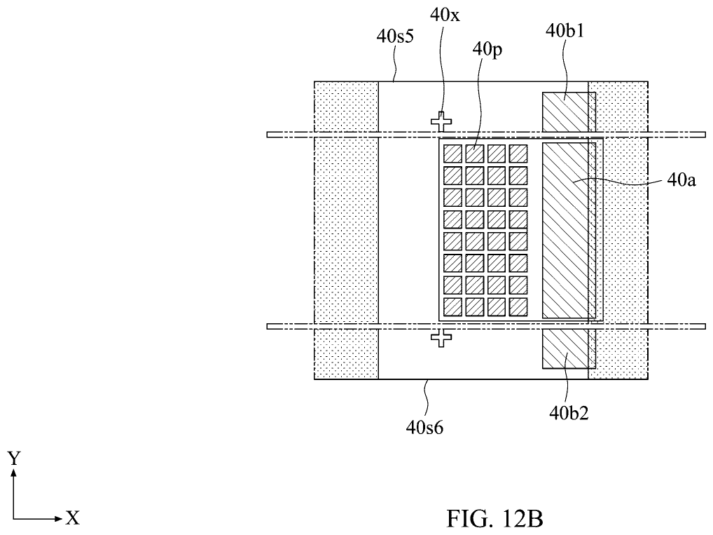

FIG. 12A illustrates one or more stages of an example of a method for manufacturing a package structure (e.g., the package structure 300) according to some embodiments of the present disclosure.

As shown in FIG. 12A, the package structure 400 (or the carrier 40) may be singulated by a blade 38 to form a package structure 300 as shown in FIG. 7.

FIG. 12B is a top view of a box B12b in FIG. 12A. The edge portion of the carrier 40 may be removed by a singulation process. The alignment mark 40x and the supporters 40b1 and 40b2 can be found in the package structure 400, while also being removed by, e.g., a singulation process, during the manufacture of the package structure 300. The alignment mark 40x and the supporters 40b1 and 40b2 may not be found in the package structure 300. Hence, the design of the routing/layout of the package structure 300 would not be severely impacted, and the present disclosure can be implemented or applied to the baseline manufacturing process.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of manufacturing a package structure, comprising:
providing a carrier, wherein the carrier comprises an alignment mark; and
attaching a mold chase to a first region of the carrier,
wherein the alignment mark is outside the first region.

2. The method of claim 1, wherein the mold chase comprises a cavity directly above the alignment mark.

3. The method of claim 2, wherein the carrier comprises a plurality of conductive pads exposed to the cavity.

4. The method of claim 3, wherein the alignment mark overlaps the conductive pads in a first direction substantially perpendicular to a long side of the carrier.

5. The method of claim 1, further comprising forming an encapsulation layer on the carrier, wherein the alignment mark is separated from the encapsulation layer.

6. The method of claim 5, wherein the encapsulation layer is separated from a cavity defined by the mold chase.

7. The method of claim 1, wherein the carrier comprises a supporter overlapping the alignment mark in a second direction substantially parallel to a long side of the carrier.

8. The method of claim 1, wherein the mold chase is separated from the alignment mark.

9. A method of manufacturing a package structure, comprising:
providing a carrier comprising a first long side and a first supporter disposed adjacent to the first long side; and
attaching a semiconductor die to the carrier,
wherein the first supporter is free from overlapping the semiconductor die in a first direction substantially parallel to the first long side.

10. The method of claim 9, further comprising removing the first supporter.

11. The method of claim 9, wherein the first supporter comprises a stacking structure.

12. The method of claim 9, wherein the carrier comprises a second long side opposite to the first long side and a second supporter disposed adjacent to the second long side, wherein the second supporter is free from overlapping the semiconductor die in the first direction.

13. The method of claim 9, wherein the first supporter is embedded in a dielectric layer of the carrier.

14. The method of claim 9, further comprising attaching a mold chase to the carrier, wherein the mold chase is above the first supporter.

15. The method of claim 14, wherein the first supporter is configured to support the mold chase for alleviating a deformation of the carrier.

16. The method of claim 14, wherein the first supporter is free from overlapping a plurality of conductive pads of the carrier in the first direction.

17. A package structure, comprising:
a carrier comprising a long side;
a plurality of conductive pads disposed at a first surface of the carrier; and
an alignment mark disposed at the first surface,
wherein the alignment mark overlaps the conductive pads in a first direction substantially perpendicular to the long side.

18. The package structure of claim 17, further comprising a first supporter embedded in the carrier, wherein the alignment mark overlaps the first supporter in a second direction substantially perpendicular to the first direction.

19. The package structure of claim 18, further comprising an encapsulation layer separated from the alignment mark and the first supporter.

20. The package structure of claim 19, wherein the conductive pads are exposed by the encapsulation layer.
